(19) United States
(12) Patent Application Publication
(10) Pub. No.: US 2025/0267377 A1
(43) Pub. Date: Aug. 21, 2025

(54) DIGITAL PIXEL AND IMAGE SENSOR INCLUDING THE SAME

(71) Applicant: DB HiTek Co., Ltd., Seoul (KR)

(72) Inventors: Ju Hwan JUNG, Eumseong-gun (KR); Sang Won YUN, Daegu (KR); Ick Su JEON, Chungju-si (KR)

(73) Assignee: DB HiTek Co., Ltd., Seoul (KR)

(21) Appl. No.: 18/642,663

(22) Filed: Apr. 22, 2024

(30) Foreign Application Priority Data
Feb. 20, 2024 (KR) 10-2024-0023896

(51) Int. Cl. H04N 25/771; H04N 25/532

(52) U.S. Cl. CPC H04N 25/771; H04N 25/532

(57) ABSTRACT

A digital pixel comprising: a photo diode to generate an optical signal based on incident light; a storage diode to store the optical signal generated by the photo diode; a floating diffusion to output a light detection signal based on the optical signal; a first transfer gate that is electrically connected to the photo diode and the storage diode to transfer the optical signal generated by the photo diode to the storage diode; and a second transfer gate that is disposed on one side of the storage diode to maintain the optical signal stored in the storage diode and improve efficiency of transferring the stored optical signal to the floating diffusion, wherein the second transfer gate includes at least one slot formed in a through structure.

### CROSS-REFERENCE TO RELATED APPLICATION

This application claims priority under 35 U.S.C § 119 to Korean Patent Application No. 10-2024-0023896 filed on Feb. 20, 2024, in the Korean Intellectual Property Office, the entire contents of which are hereby incorporated by reference.

### BACKGROUND

### Field

The present disclosure relates to a digital pixel that can maintain the form of a 7-transistor global shutter (7Tr. G/S) but can secure the same or similar dark electron characteristics as a 6-transistor global shutter (6Tr. G/S) by forming a slot in the transfer gate formed above the storage diode, and an image sensor including the same.

### Description of Related Art

The content described in this section provides background information only for the present embodiment and does not constitute prior art.

Driving methods for digital pixels are largely classified into a rolling shutter method and a global shutter method, and the global shutter is divided into a charge domain global shutter and a voltage domain global shutter.

Here, the charge domain global shutter utilizes a scheme that simultaneously resets the pixel array, transfers electrons accumulated in the photo diodes (PDs) to the storage diodes (SDs), and reads them out in sequence.

In this case, as the storage diode of a 7-transistor global shutter (7Tr. G/S) does not have a pinning layer on the silicon surface, it exhibits high performance in terms of fast operation speed and parasitic light sensitivity (PLS) but has a structure vulnerable to dark electrons generated from the silicon surface.

On the other hand, in the case of a 6-transistor global shutter (6Tr. G/S), a pinning layer is added when a storage diode is formed, and the upper poly gate of the storage diode is not formed. At this time, due to this configuration, the 6-transistor global shutter is known to have a structure with good dark electron characteristics, although the PLS characteristics are deteriorated because the storage diode is formed in a deeper region from the silicon surface compared with the storage diode of a 7-transistor global shutter.

### SUMMARY

An object of the present disclosure is to provide a digital pixel that can maintain the form of a 7-transistor global shutter but can secure the same or similar dark electron characteristics as a 6-transistor global shutter by forming a slot in the transfer gate formed above the storage diode, and an image sensor including the same. That is, an object of the present disclosure is to provide a digital pixel that maintains PLS-related characteristics at the level of a 7-transistor global shutter and has dark electron-related characteristics comparable to a 6-transistor global shutter by forming a slot in a specific transfer gate, and an image sensor including the same.

Another object of the present disclosure is to provide a digital pixel in which a P-type semiconductor region is formed in a portion of the storage diode by injecting P-type ions into the slot formed in the transfer gate, and an image sensor including the same.

The objects of the present disclosure are not limited to those mentioned above, and other objects and advantages of the present disclosure that are not mentioned can be understood by the following description and will be more clearly understood by embodiments of the present disclosure. Additionally, it will be readily apparent that the objects and advantages of the present disclosure can be realized by the means and combinations thereof indicated in the patent claims.

According to some aspects of the disclosure, a digital pixel comprises; a photo diode to generate an optical signal based on incident light, a storage diode to store the optical signal generated by the photo diode, a floating diffusion to output a light detection signal based on the optical signal, a first transfer gate that is electrically connected to the photo diode and the storage diode to transfer the optical signal generated by the photo diode to the storage diode, and a second transfer gate that is disposed on one side of the storage diode to maintain the optical signal stored in the storage diode and improve efficiency of transferring the stored optical signal to the floating diffusion, wherein the second transfer gate includes at least one slot formed in a through structure.

According to some aspects, the second transfer gate is disposed above the storage diode.

According to some aspects, the plurality of slots are arranged in a pattern on the second transfer gate.

According to some aspects, a shape of the slot includes at least one of a cylinder, a prism, a truncated cone, and a truncated pyramid.

According to some aspects, the prism includes at least one of a triangular prism, a tetragonal prism, a pentagonal prism, a hexagonal prism, and an octagonal prism; and the tetragonal prism includes at least one of a square prism and a rectangular prism.

According to some aspects, the plurality of slots having a square prism shape are arranged at equal intervals on the second transfer gate.

According to some aspects, the plurality of slots having a rectangular prism shape are arranged parallel to each other.

According to some aspects, the storage diode includes a P-type semiconductor region formed by injection of P-type ions.

According to some aspects, the P-type semiconductor region is formed in a region adjacent to the second transfer gate among a surface area of the storage diode.

According to some aspects, the P-type semiconductor region is formed based on that the P-type ions injected into the second transfer gate pass through the slot included in the second transfer gate.

According to some aspects of the disclosure, an image sensor comprises; a digital pixel array including at least one digital pixel that detects incident light from an outside and outputs a digital pixel signal based on the incident light, a pixel driver configured to output a control signal for controlling the digital pixel array, and a digital logic circuit configured to perform digital signal processing on the digital pixel signal received from the digital pixel array, wherein the digital pixel includes a photo detector that outputs a light detection signal based on the incident light, and an analog digital converter (ADC) that converts the light detection signal to output the digital pixel signal, wherein the photo detector includes a photo diode that generates an optical signal based on the incident light, a storage diode that stores the optical signal generated by the photo diode, a floating diffusion that outputs the light detection signal based on the optical signal, a first transfer gate that is electrically connected to the photo diode and the storage diode to transfer the optical signal generated by the photo diode to the storage diode, and a second transfer gate that is disposed on one side of the storage diode to maintain the optical signal stored in the storage diode and improve efficiency of transferring the stored optical signal to the floating diffusion, wherein the second transfer gate includes at least one slot formed in a through structure.

According to some aspects of the disclosure, an image sensor comprises; a digital pixel array configured to detect incident light from an outside and output a digital pixel signal based on the incident light, a pixel driver configured to output a control signal for controlling the digital pixel array; and a digital logic circuit configured to perform digital signal processing on the digital pixel signal received from the digital pixel array, wherein the digital pixel array includes at least one digital pixel including a photo detector that outputs a light detection signal based on the incident light, an analog digital converter that converts the light detection signal output from the digital pixel to output the digital pixel signal, and a memory cell to store the light detection signal, where each column of the digital pixel array in which multiple digital pixels are arranged includes one analog digital converter and one memory cell, wherein the photo detector includes a photo diode that generates an optical signal based on the incident light, a storage diode that stores the optical signal generated by the photo diode, a floating diffusion that outputs the light detection signal based on the optical signal, a first transfer gate that is electrically connected to the photo diode and the storage diode to transfer the optical signal generated by the photo diode to the storage diode, and a second transfer gate that is disposed on one side of the storage diode to maintain the optical signal stored in the storage diode and improve efficiency of transferring the stored optical signal to the floating diffusion, wherein the second transfer gate includes at least one slot formed in a through structure.

According to some aspects, the second transfer gate is disposed above the storage diode.

According to some aspects, the plurality of slots are arranged in a pattern on the second transfer gate.

According to some aspects, a shape of the slot includes at least one of a cylinder, a prism, a truncated cone, and a truncated pyramid.

According to some aspects, the prism includes at least one of a triangular prism, a tetragonal prism, a pentagonal prism, a hexagonal prism, and an octagonal prism; and the tetragonal prism includes at least one of a square prism and a rectangular prism.

According to some aspects, the plurality of slots having a square prism shape are arranged at equal intervals on the second transfer gate.

According to some aspects, the plurality of slots having a rectangular prism shape are arranged parallel to each other.

According to some aspects, the storage diode includes a P-type semiconductor region formed by injection of P-type ions.

According to some aspects, the P-type semiconductor region is formed in a region adjacent to the second transfer gate among a surface area of the storage diode.

According to some aspects, the P-type semiconductor region is formed based on that the P-type ions injected into the second transfer gate pass through the slot included in the second transfer gate.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

A digital pixel and an image sensor including the same according to some embodiments of the present disclosure can maintain the form of a 7-transistor global shutter and secure the same or similar dark electron characteristics as a 6-transistor global shutter (6Tr. G/S) by forming a slot in the transfer gate formed above the storage diode. In other words, a digital pixel and an image sensor including the same according to some embodiments of the present disclosure have a significant effect of ensuring both PLS-related characteristics and dark electron-related characteristics.

Further, in a digital pixel and an image sensor including the same according to some embodiments of the present disclosure, a P-type semiconductor region can be formed in a portion of the storage diode by injecting P-type ions into the slot formed in the transfer gate.

In addition to the above-described content, specific effects of the present disclosure are described below while explaining specific details for carrying out the disclosure.

### BRIEF DESCRIPTION OF THE DRAWINGS

FIGS. 1A and 1B are a block diagram of an image sensor according to some embodiments of the present disclosure.

FIGS. 2A to 2C are conceptual diagrams for explaining a photo detector included in a digital pixel according to some embodiments of the present disclosure.

FIGS. 3A to 3D are plan views illustrating a photo detector included in a digital pixel according to some embodiments of the present disclosure.

FIG. 4, a description will be given of the P-type semiconductor region formed in the storage diode SD according to some embodiments of the present disclosure.

FIG. 5 shows the magnitudes of voltages applied over time to individual transistors of the gate structure.

### DETAILED DESCRIPTION

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

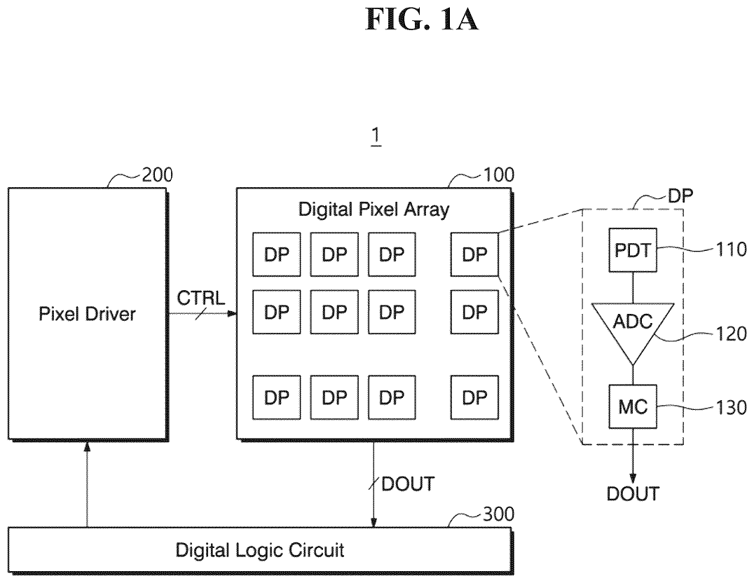

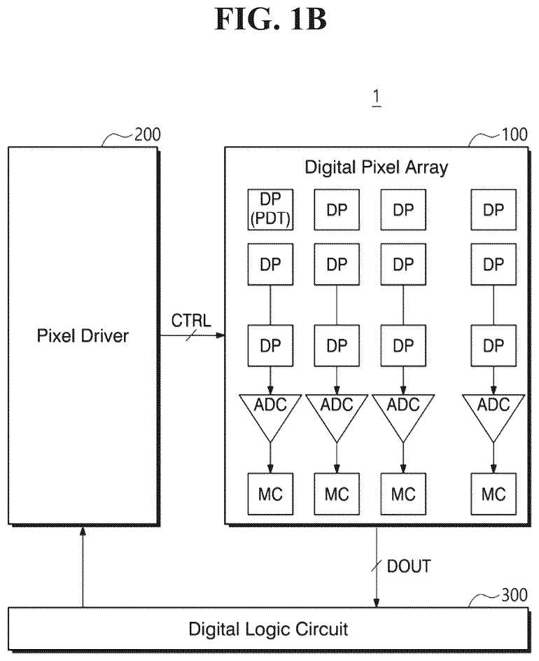

Hereinafter, a digital pixel and an image sensor including the same according to an embodiment of the present disclosure will be described with reference to FIGS. 1A to 5.

FIGS. 1A and 1B are a block diagram of an image sensor according to some embodiments of the present disclosure.

With reference to FIGS. 1A and 1B, the image sensor 1 according to some embodiments of the present disclosure may include a digital pixel array 100, a pixel driver 200, and a digital logic circuit 300.

Here, FIG. 1A shows a structure in which each digital pixel DP included in the digital pixel array 100 includes a photo detector (PDT) 110, an analog digital converter (ADC) 120, and a memory cell (MC) 130. In addition, FIG. 1B shows a structure in which each digital pixel DP includes a photo detector 110 only, and each column of the digital pixel array 100 includes multiple digital pixels DP, one analog digital converter 120, and one memory cell 130. That is, comparing FIG. 1A and FIG. 1B, FIG. 1A shows a structure in which each of multiple digital pixels DP includes a photo detector (PDT) 110, an analog digital converter (ADC) 120, and a memory cell (MC) 130; FIG. 1B shows a structure in which only one analog digital converter (ADC) 120 and one memory cell (MC) 130 are arranged for each column of digital pixels DP including a photo detector (PDT) 110. In the following description, for convenience of explanation, the image sensor 1 is assumed to have a structure as shown in FIG. 1A.

The digital pixel array 100 may include a plurality of digital pixels DP. Each digital pixel DP may detect incident light from the outside and store data corresponding to the detected incident light or may output a digital pixel signal DOUT based on the incident light. Here, the digital pixel DP may include a photo detector (PDT) 110, an analog digital converter (ADC) 120, and a memory cell (MC) 130. The photo detector (PDT) 110 may detect incident light from the outside, generate an optical signal, and output a light detection signal based on the generated optical signal. The analog digital converter (ADC) 120 may convert a light detection signal (analog signal) detected by the photo detector (PDT) 110 into a digital signal and output a digital pixel signal DOUT. The memory cell (MC) 130 may store a digital pixel signal DOUT corresponding to the light detection signal. The memory cell (MC) 130 may output the stored digital pixel signal DOUT to the digital logic circuit 300.

The pixel driver 200 may output a control signal CTRL for controlling the digital pixel array 100 under the control of the digital logic circuit 300.

The digital logic circuit 300 may perform digital signal processing on the digital pixel signal DOUT received from the digital pixel array 100 and provide the processing result to an external device (e.g., image signal processor (ISP) or application processor (AP)).

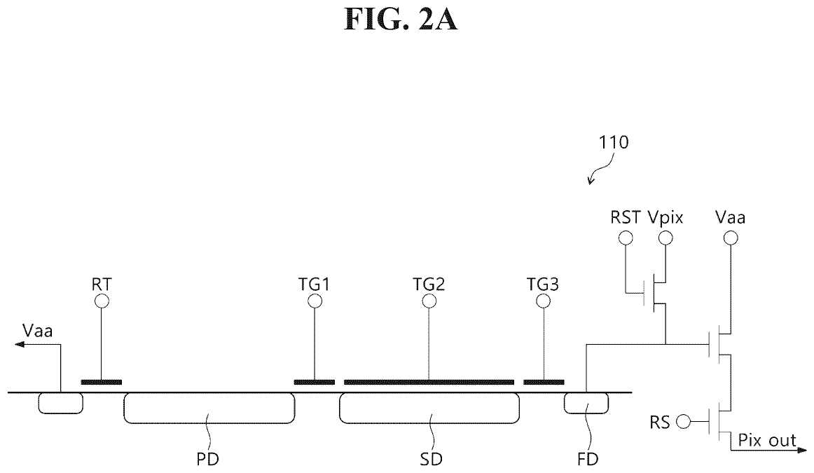

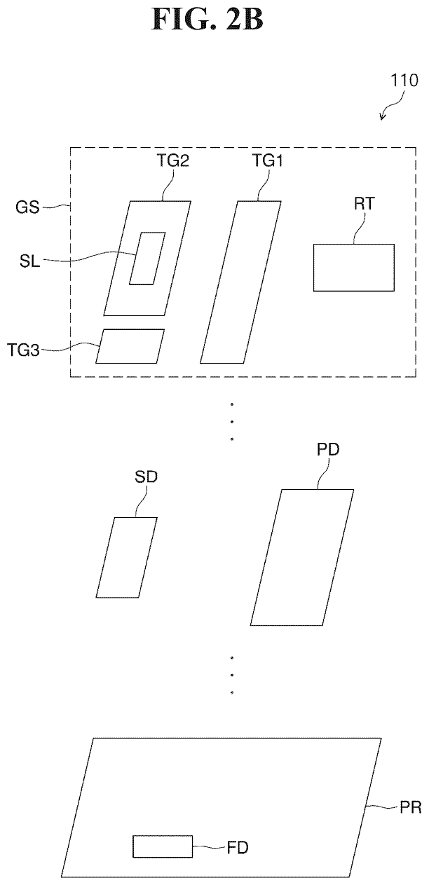

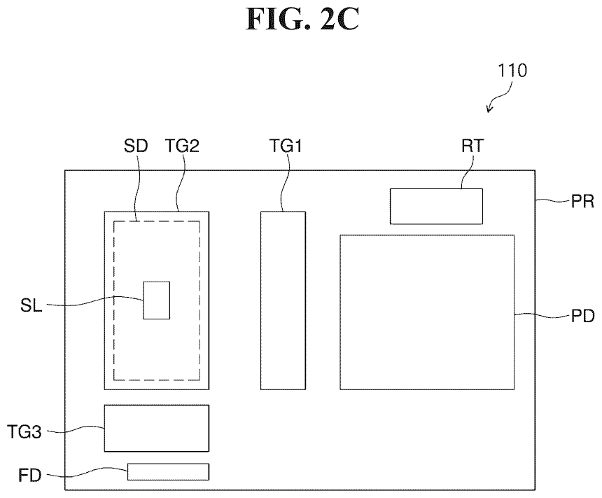

Next, a description will be given of a digital pixel DP and a photo detector (PDT) 110 included therein according to some embodiments of the present disclosure with reference to FIGS. 2A to 2C.

FIGS. 2A to 2C are conceptual diagrams for explaining a photo detector included in a digital pixel according to some embodiments of the present disclosure. Specifically, FIG. 2A illustrates a circuit diagram of the photo detector 110, FIG. 2B illustrates a conceptual perspective view to depict components included in the photo detector 110, and FIG. 2C illustrates a plan view of the photo detector 110.

With reference to FIGS. 1A to 2C, the photo detector 110 may generate an optical signal based on incident light from the outside and output a light detection signal corresponding to the generated optical signal. Here, the light detection signal may be an analog signal. In the present disclosure, an optical signal may be referred to as electrons or electric charges. The photo detector 110 may include a pixel region (hereinafter referred to as “PR”), a photo diode (hereinafter referred to as “PD”), a storage diode (hereinafter referred to as “SD”), and a gate structure (hereinafter referred to as “GS”) including one or more transistors. A floating diffusion (hereinafter referred to as “FD”) may be formed in the pixel region PR. The gate structure GS may include a plurality of transistors constituting a readout circuit, such as a reset transistor (hereinafter referred to as “RT”), a first transfer gate (hereinafter referred to as “TG1”), a second transfer gate (hereinafter referred to as “TG2”), and a third transfer gate (hereinafter referred to as “TG3”).

The pixel region PR is a region electrically activated through a doping process, and may be a region where a photo diode PD, a storage diode SD, and a gate structure GS are formed. As an example, the pixel region PR may be a region in which channels of individual transistors (e.g., TG1, TG2, TG3, etc.) are formed to move and store charges generated from the photo diode PD or transfer charges to other circuit elements.

In some examples, the material of the pixel region PR may include silicon, but embodiments of the present disclosure are not limited thereto.

Here, a floating diffusion FD may be formed in the pixel region PR. The floating diffusion FD may output a light detection signal based on an optical signal (electrons or charges) that is generated from the photo diode PD and stored in the storage diode SD. At this time, the floating diffusion FD may receive an optical signal from the storage diode SD through the third transfer gate TG3. In this case, the optical transmission efficiency of the optical signal transmitted from the storage diode SD to the floating diffusion FD may be improved by the second transfer gate TG2. The charge quantity (Q) of the floating diffusion FD can be converted by the capacitance (CFD) of the floating diffusion FD into a voltage difference (=Q/CFD). The voltage level of the light detection signal may correspond to the voltage level of the floating diffusion FD.

The photo diode PD may be a photoelectric conversion element that generates an optical signal based on incident light from the outside. A photoelectric conversion element can generate and accumulate charges in proportion to the amount of light incident from the outside. The photoelectric conversion element can convert incident light into an electrical signal. For example, the photoelectric conversion element may be a photo diode PD, a photo transistor, a photo gate, a pinned photo diode (PPD), or a combination thereof. In the following description, for convenience of explanation, it is assumed that the photoelectric conversion element is a photo diode PD as shown in FIGS. 2A to 2C.

In some examples, the photo diode PD may be electrically connected to the reset transistor RT and the first transfer gate TG1.

The storage diode SD may temporarily store photo charges generated in the photo diode PD. Although the diode SD is shown as an example of a light receiving element in FIGS. 2A to 2C, the present disclosure is not limited thereto, and the shape of the light receiving element may be modified as much as desired. For example, the storage diode SD may be implemented with a capacitor. In this case, the optical storage efficiency of the storage diode SD may be improved by the second transfer gate TG2. That is, the second transfer gate TG2 may serve to maintain the optical signal (electrons) stored in the storage diode SD. A P-type semiconductor region may be formed in a portion of the storage diode SD. For example, in the surface area of the storage diode SD, a P-type semiconductor region may be formed by P-type ions having passed through a slot (hereinafter referred to as “SL”) formed in the second transfer gate TG2. A detailed description of this will be given later.

The photo charges accumulated in the photo diode PD are not directly transferred to the floating diffusion FD, but are temporarily stored in the storage diode SD and then transferred to the floating diffusion FD, which enables implementation of global shutter operation of the image sensor 1. In other words, by accumulating information (e.g., photo charges) stored in a plurality of digital pixels DP in the same period and storing this in the storage diodes SD, the time points at which the photo diodes PD are exposed can be made the same even if the periods in which analog-to-digital conversion operations are performed are different, so that it can operate as a global shutter.

The gate structure GS may include a plurality of transistors as described above. In some examples, the gate structure GS may include a reset transistor RT and first to third transfer gates TG1 to TG3. The material of the reset transistor RT and the first to third transfer gates TG1 to TG3 may include poly silicon, but embodiments of the present disclosure are not limited thereto.

The reset transistor RT can serve to reset all pixels simultaneously. In other words, the reset transistor RT may discharge the charge accumulated in the photo diode PD based on a discharge signal. The reset transistor RT may be turned on or turned off by a discharge signal. Here, the reset transistor RT may be referred to as a global reset gate.

The first transfer gate TG1 may be electrically connected to the photo diode PD and the storage diode SD. In some examples, the first transfer gate TG1 may serve as a gate that transfers an optical signal (electrons or charges) from the photo diode PD to the storage diode SD.

The second transfer gate TG2 may be electrically connected to the storage diode SD. Here, the second transfer gate TG2 may be disposed above the storage diode SD.

In some examples, the second transfer gate TG2 may serve to control keeping electrons stored in the storage diode SD from escaping or to more effectively move electrons on the storage diode SD to the floating diffusion FD. In other words, the second transfer gate TG2 may serve to maintain an optical signal (electrons) stored in the storage diode SD and also serve to improve transfer efficiency of transferring the optical signal (electrons) stored in the storage diode SD to the floating diffusion FD. Meanwhile, the second transfer gate TG2 may include a slot SL. In other words, the second transfer gate TG2 may include at least one slot SL formed in a through structure. A detailed description of a slot SL formed in the second transfer gate TG2 will be given later.

The third transfer gate TG3 may transfer the charge accumulated in the storage diode SD to the floating diffusion FD. The charge quantity (Q) of the floating diffusion FD transferred through the third transfer gate TG3 may be converted by the capacitance (CFD) of the floating diffusion FD into a voltage difference (=Q/CFD). The voltage level of the light detection signal may correspond to the voltage level of the floating diffusion FD.

In the circuit diagram of FIG. 2A, Vaa refers to the analog power supply voltage, RST refers to the reset voltage for resetting the floating diffusion FD, Vpix refers to the pixel voltage, RS refers to the row selection signal, and Pix out refers to the pixel output.

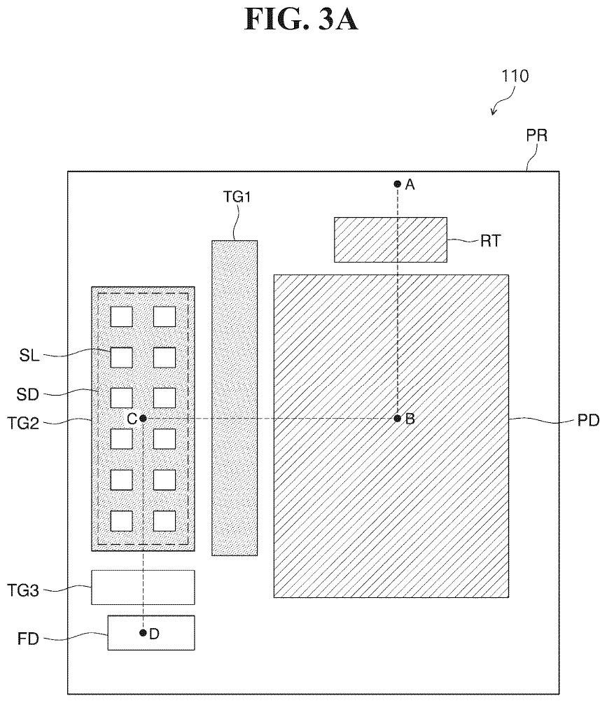

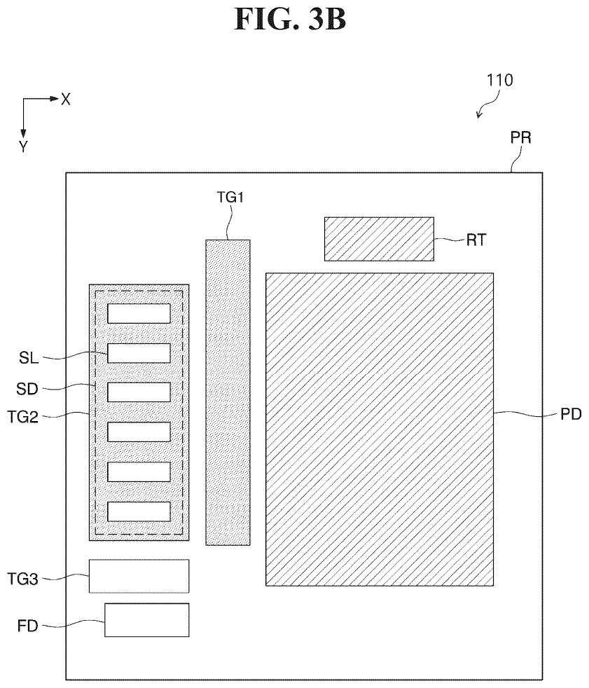

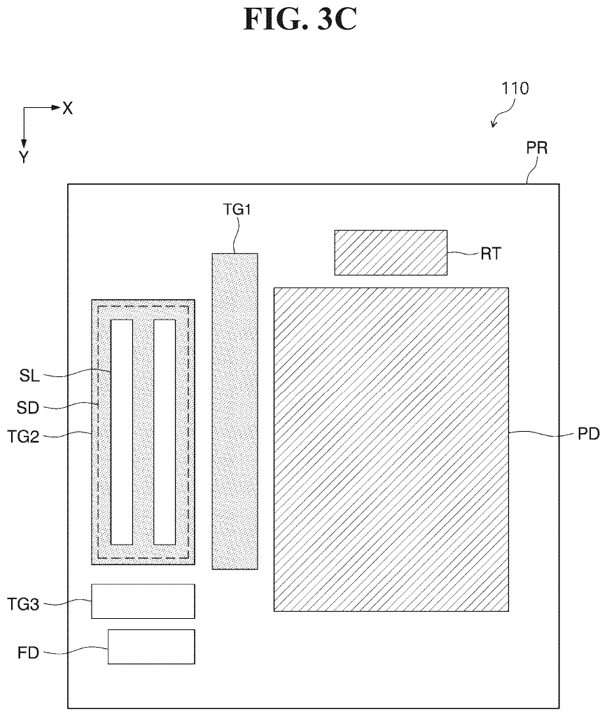

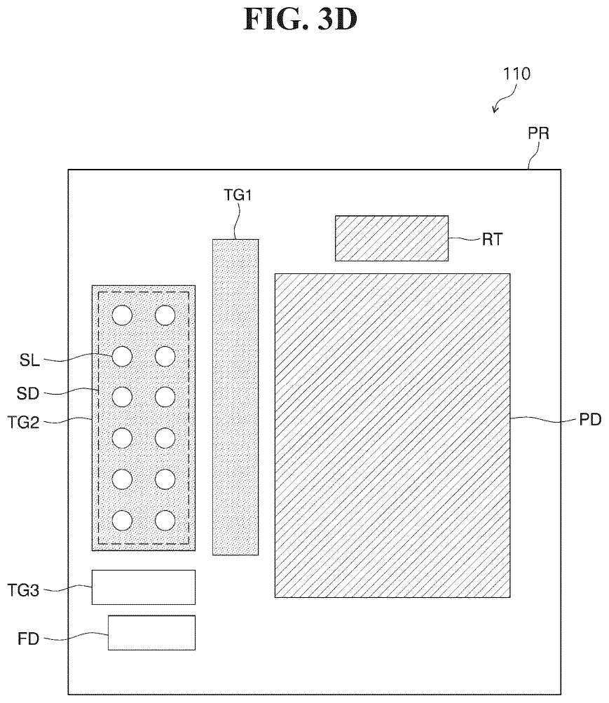

Next, a description will be given of the structure of the slot SL, the second transfer gate TG2 including the same and the photo detector 110 according to some embodiments of the present disclosure with reference to FIGS. 3A to 3D.

FIGS. 3A to 3D are plan views illustrating a photo detector included in a digital pixel according to some embodiments of the present disclosure.

With reference to FIGS. 3A to 3D, the second transfer gate TG2 according to some embodiments of the present disclosure may include a slot SL. In other words, the second transfer gate TG2 may include at least one slot SL formed in a through structure. Here, the slot SL may be referred to as an opening, a through hole, etc. For example, the slot SL may be formed to penetrate from one surface of the second transfer gate TG2 to another surface. For instance, as shown in FIGS. 3A to 3D, the slot SL may be formed to penetrate from the upper surface of the second transfer gate TG2 toward the lower surface. However, embodiments of the present disclosure are not limited thereto.

In some examples, the slots SL may be arranged in a pattern on the second transfer gate TG2. In other words, multiple slots SL may be arranged in a pattern on the second transfer gate TG2.

For example, the shape of individual slots SL arranged in a pattern may be predefined in various forms. For instance, the slots SL may have various shapes such as a cylinder, prism (e.g., triangular prism, square prism, pentagonal prism, hexagonal prism, or octagonal prism), truncated cone, or truncated pyramid (e.g., truncated triangular pyramid, truncated square pyramid, truncated pentagonal pyramid, truncated hexagonal pyramid, or truncated octagonal pyramid). However, embodiments of the present disclosure are not limited thereto. In FIGS. 3A to 3C, the slot SL is formed as a square prism and is shown as having a quadrilateral shape in a plan view; in FIG. 3D, the slot SL is formed as a cylinder and is shown as having a circular shape in a plan view.

Here, when the slot SL has the shape of a tetragonal prism, the slot SL according to some embodiments of the present disclosure may have the shape of a square prism or a rectangular prism. In FIG. 3A, the slot SL is shown as being formed as a square prism; in FIGS. 3B and 3C, the slot SL is shown as being formed as a rectangular prism. Specifically, FIG. 3B shows a slot SL formed in the shape of a rectangular prism whose length in a first direction (X direction) is longer than that in a second direction (Y direction), and FIG. 3C shows a slot SL formed in the shape of a rectangular prism whose length in a second direction (Y direction) is longer than that in a first direction (X direction).

As an example, when the slot SL has the shape of a square prism, multiple slots SL having the shape of a square prism may be uniformly disposed on the second transfer gate TG2. For instance, as shown in FIG. 3A, multiple square prism-shaped slots SL may be uniformly arranged at the same distance from each other on the second transfer gate TG2. However, embodiments of the present disclosure are not limited thereto, and the distances between multiple slots SL formed in the shape of a square prism in the second transfer gate TG2 may be different from each other.

As another example, when the slot SL has the shape of a rectangular prism, multiple slots SL having the shape of a rectangular prism may be arranged parallel to each other on the second transfer gate TG2. For instance, as shown in FIGS. 3B and 3C, multiple slots SL having the shape of a rectangular prism may be arranged parallel to each other on the second transfer gate TG2. However, embodiments of the present disclosure are not limited thereto, and the arrangement angles of the plural slots SL formed in the shape of a rectangular prism in the second transfer gate TG2 may be different from each other.

Meanwhile, through the slot SL, a P-type semiconductor region may be formed in a portion of the storage diode SD. For example, a P-type semiconductor region may be formed in the surface area of the storage diode SD by P-type ions having passed through the slot SL included in the second transfer gate TG2. Here, the surface area of the storage diode SD may be a region adjacent to the second transfer gate TG2 among multiple regions of the storage diode SD.

To be more specific, when P-type ions are injected into the second transfer gate TG2, the ions may pass through the slot SL formed in a through structure and reach the storage diode SD. At this time, a P-type semiconductor region may be formed on the surface area (silicon surface) of the storage diode SD by the P-type ions having reached the storage diode SD.

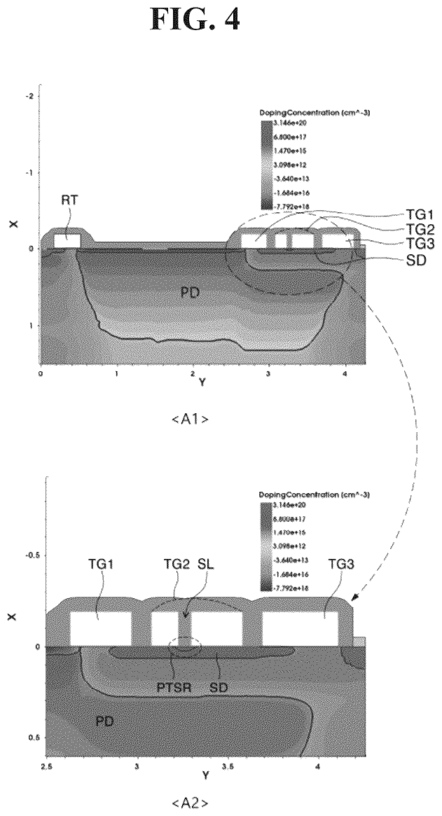

Next, with reference to FIG. 4, a description will be given of the P-type semiconductor region formed in the storage diode SD according to some embodiments of the present disclosure.

FIG. 4 shows process simulation results according to some embodiments of the present disclosure.

Referring to FIGS. 3A and 4, FIG. 4 shows the results of simulation on the cross section of the photo detector 110 indicated by A-B-C-D in FIG. 3A performed through technology computer-aided design (TCAD). Specifically, part <A1> of FIG. 4 shows a result of simulation on the cross section of the photo detector 110 indicated by A-B-C-D in FIG. 3A, and part <A2> of FIG. 4 is an enlarged view of a region in part <A1> of FIG. 4.

With reference to FIG. 3A and parts <A1> and <A2> of FIG. 4, a P-type semiconductor region (hereinafter referred to as “PTSR”) may be formed in a portion of the storage diode SD according to some embodiments of the present disclosure.

For example, a P-type semiconductor region PTSR may be formed in the surface area of the storage diode SD by P-type ions having passed through the slot SL included in the second transfer gate TG2. Here, the surface area of the storage diode SD may be a region adjacent to the second transfer gate TG2 among multiple regions of the storage diode SD.

To be more specific, when P-type ions are injected into the second transfer gate TG2, the ions may pass through the slot SL formed in a through structure and reach the storage diode SD. At this time, a P-type semiconductor region PTSR may be formed on the surface area (silicon surface) of the storage diode SD by the P-type ions having reached the storage diode SD.

Referring to the doping concentration (expressed in color) shown in part <A2> of FIG. 4, it can be confirmed that a P-type semiconductor region PTSR is formed in the surface area of the storage diode SD (a region adjacent to the second transfer gate TG2).

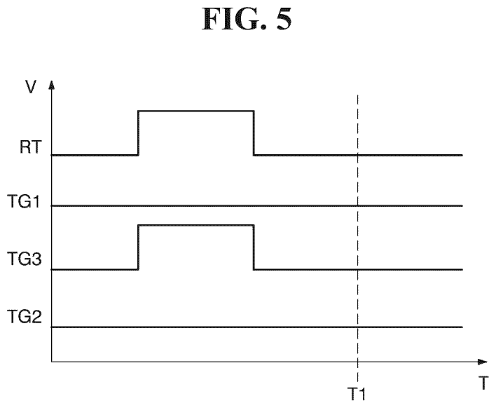

FIG. 5 shows the magnitudes of voltages applied over time to individual transistors of the gate structure.

Referring to FIGS. 3A and 5, FIG. 5 shows the magnitudes of voltages (V) applied over time to the reset transistor RT and the first to third transistors TG1 to TG3 included in the photo detector 110 of FIG. 3A.

In FIG. 5, the horizontal axis represents time (T), and the vertical axis represents the magnitude of applied voltage (V). Specifically, FIG. 5 shows that a voltage is applied to the reset transistor RT and the third transfer gate TG3 at a specific point in time.

Through this, the photo diode PD can be reset by applying a voltage to the reset transistor RT, and the storage diode SD can be reset by applying a voltage to the third transfer gate TG3.

The quantitative amount of dark electrons generated in the storage diode SD at time T1 through the voltage application process of FIG. 5 is calculated as shown in <Table 1> below. That is, <Table 1> below shows a comparison result in quantitative amount of dark electrons (DE) over time (T) between simulations performed on a 7-transistor global shutter (7Tr. G/S) with a normal (existing) structure in which a slot SL is not formed and a 7-transistor global shutter (7Tr. G/S) with a structure shown in FIG. 3A (in which a slot SL is formed).

TABLE 1

| | Existing structure | This disclosure |
|---|---|---|
| Dark electrons (DE, #/sec) | 203.7 | 37.35 |

As a result of the simulation, the dark electrons in the existing structure are calculated to be 203.7 electrons/sec, and the dark electrons for the improved structure of the present disclosure are calculated to be 37.35 electrons/sec.

Through this, it can be seen that, when a slot SL is formed in the second transfer gate TG2 as in the present disclosure and P-type ions are injected into the second transfer gate TG2, the characteristics regarding dark electrons can be improved while maintaining the form of a 7-transistor global shutter (7Tr. G/S). That is, the photo detector 110 and the digital pixel DP including the same according to some embodiments of the present disclosure can secure both PLS-related characteristics and dark electron-related characteristics.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A digital pixel comprising:
a photo diode to generate an optical signal based on incident light;
a storage diode to store the optical signal generated by the photo diode;
a floating diffusion to output a light detection signal based on the optical signal;
a first transfer gate that is electrically connected to the photo diode and the storage diode to transfer the optical signal generated by the photo diode to the storage diode; and
a second transfer gate that is disposed on one side of the storage diode to maintain the optical signal stored in the storage diode and improve efficiency of transferring the stored optical signal to the floating diffusion,
wherein the second transfer gate includes at least one slot formed in a through structure.

2. The digital pixel of claim 1, wherein the second transfer gate is disposed above the storage diode.

3. The digital pixel of claim 1, wherein the plurality of slots are arranged in a pattern on the second transfer gate.

4. The digital pixel of claim 3, wherein a shape of the slot includes at least one of a cylinder, a prism, a truncated cone, and a truncated pyramid.

5. The digital pixel of claim 4, wherein:
the prism includes at least one of a triangular prism, a tetragonal prism, a pentagonal prism, a hexagonal prism, and an octagonal prism; and
the tetragonal prism includes at least one of a square prism and a rectangular prism.

6. The digital pixel of claim 5, wherein the plurality of slots having a square prism shape are arranged at equal intervals on the second transfer gate.

7. The digital pixel of claim 5, wherein the plurality of slots having a rectangular prism shape are arranged parallel to each other.

8. The digital pixel of claim 1, wherein the storage diode includes a P-type semiconductor region formed by injection of P-type ions.

9. The digital pixel of claim 8, wherein the P-type semiconductor region is formed in a region adjacent to the second transfer gate among a surface area of the storage diode.

10. The digital pixel of claim 9, wherein the P-type semiconductor region is formed based on that the P-type ions injected into the second transfer gate pass through the slot included in the second transfer gate.

11. An image sensor comprising:
a digital pixel array including at least one digital pixel that detects incident light from an outside and outputs a digital pixel signal based on the incident light;
a pixel driver configured to output a control signal for controlling the digital pixel array; and
a digital logic circuit configured to perform digital signal processing on the digital pixel signal received from the digital pixel array,
wherein the digital pixel includes a photo detector that outputs a light detection signal based on the incident light, and an analog digital converter (ADC) that converts the light detection signal to output the digital pixel signal,
wherein the photo detector includes a photo diode that generates an optical signal based on the incident light, a storage diode that stores the optical signal generated by the photo diode, a floating diffusion that outputs the light detection signal based on the optical signal, a first transfer gate that is electrically connected to the photo diode and the storage diode to transfer the optical signal generated by the photo diode to the storage diode, and a second transfer gate that is disposed on one side of the storage diode to maintain the optical signal stored in the storage diode and improve efficiency of transferring the stored optical signal to the floating diffusion,
wherein the second transfer gate includes at least one slot formed in a through structure.

12. An image sensor comprising:
a digital pixel array configured to detect incident light from an outside and output a digital pixel signal based on the incident light;
a pixel driver configured to output a control signal for controlling the digital pixel array; and
a digital logic circuit configured to perform digital signal processing on the digital pixel signal received from the digital pixel array,
wherein the digital pixel array includes at least one digital pixel including a photo detector that outputs a light detection signal based on the incident light, an analog digital converter that converts the light detection signal output from the digital pixel to output the digital pixel signal, and a memory cell to store the light detection signal, where each column of the digital pixel array in which multiple digital pixels are arranged includes one analog digital converter and one memory cell,
wherein the photo detector includes a photo diode that generates an optical signal based on the incident light, a storage diode that stores the optical signal generated by the photo diode, a floating diffusion that outputs the light detection signal based on the optical signal, a first transfer gate that is electrically connected to the photo diode and the storage diode to transfer the optical signal generated by the photo diode to the storage diode, and a second transfer gate that is disposed on one side of the storage diode to maintain the optical signal stored in the storage diode and improve efficiency of transferring the stored optical signal to the floating diffusion,
wherein the second transfer gate includes at least one slot formed in a through structure.

13. The image sensor of claim 12, wherein the second transfer gate is disposed above the storage diode.

14. The image sensor of claim 12, wherein the plurality of slots are arranged in a pattern on the second transfer gate.

15. The image sensor of claim 14, wherein a shape of the slot includes at least one of a cylinder, a prism, a truncated cone, and a truncated pyramid.

16. The image sensor of claim 15, wherein:
the prism includes at least one of a triangular prism, a tetragonal prism, a pentagonal prism, a hexagonal prism, and an octagonal prism; and
the tetragonal prism includes at least one of a square prism and a rectangular prism.

17. The image sensor of claim 16, wherein the plurality of slots having a square prism shape are arranged at equal intervals on the second transfer gate.

18. The image sensor of claim 16, wherein the plurality of slots having a rectangular prism shape are arranged parallel to each other.

19. The image sensor of claim 12, wherein the storage diode includes a P-type semiconductor region formed by injection of P-type ions.

20. The image sensor of claim 19, wherein the P-type semiconductor region is formed in a region adjacent to the second transfer gate among a surface area of the storage diode.

21. The image sensor of claim 20, wherein the P-type semiconductor region is formed based on that the P-type ions injected into the second transfer gate pass through the slot included in the second transfer gate.
